(19) United States
(12) Patent Application Publication
(10) Pub. No.: US 2024/0044970 A1
(43) Pub. Date: Feb. 8, 2024

(54) METHOD FOR EXTRACTING SURFACE TRAP LEVEL CONSIDERING OXIDE THICKNESS OF QUANTUM CAPACITOR

(71) Applicant: University of Ulsan Foundation for Industry Cooperation, Ulsan (KR)

(72) Inventor: Tae Woo KIM, Daegu (KR)

(73) Assignee: University of Ulsan Foundation for Industry Cooperation, Ulsan (KR)

(21) Appl. No.: 18/266,615

(22) PCT Filed: Dec. 10, 2021
(86) PCT No.: PCT/KR2021/018727

§ 371 Date: Jun. 12, 2023

(30) Foreign Application Priority Data
Dec. 11, 2020 (KR) 10-2020-0173729
Nov. 16, 2021 (KR) 10-2021-0157131

(51) Int. Cl. G01R 31/28

(52) U.S. Cl. CPC G01R 31/2851

(57) ABSTRACT

The present invention relates to a method for extracting a surface trap level considering an oxide thickness of a quantum capacitor, which has an effect of enabling more accurate surface trap level measurement by extracting interface trap and border trap densities using a capacitance equivalent thickness (CET) in consideration of a quantum mechanical confinement effect in a group III-V compound device.

### TECHNICAL FIELD

The present invention relates to a method for extracting a surface trap level considering an oxide thickness of a quantum capacitor.

### BACKGROUND ART

Since expandability of existing Si/SiO₂ metal-oxide-semiconductor devices has reached its limit, researches have been conducted on insulators using a high-permittivity (high-k) dielectric and channels using a group III-V compound semiconductor that can significantly increase device speeds with high electron mobility and reduce power consumption.

Particularly, high-permittivity materials such as Al₂O₃, HfO₂, La₂O₃, ZrO₂ and HfAlOx, and their nanolaminates have been extensively studied as alternate materials for SiO₂, and InₓGa₁₋ₓAs having excellent electron transport properties is a channel material, which has been considered as alternative goods for Si.

Compared to SiO₂/Si devices, high-k/Si and high-k/group III-V oxide-semiconductor field-effect-transistors (MOSFETs) have an advantage in equivalent-oxide-thickness (EOT) scaling. In the EOT scaling, a high-permittivity dielectric can exhibit a low leakage current while having a high switching speed compared to a silicon dielectric, and a group III-V compound semiconductor such as InₓGa₁₋ₓAs can exhibit better electron transport properties compared to Si as it has a high electron transfer rate, and such a high electron transfer property can contribute to high on-state currents and faster switching speeds.

However, such a high electron transfer property is due to the low effective mass of the group III-V compound semiconductor, which causes a low density of states (DOS) for a channel layer. Because of such a low DOS, a strong inversion Fermi level (E_{F}) shifts into a conduction band (E_{C}), where such a phenomenon reduces the effective barrier height between the oxide and the channel, thereby resulting in charge and discharge through tunneling of oxide traps together with channel electrons.

In MOSFETs, charged defects occurring between the insulating layer and the channel layer are mostly interface traps (Dᵢₜ) and border traps (N_{bt}). Referring to FIGS. 1a and 1b, the interface trap (Dᵢₜ) is located at the interface between the insulator and the channel. On the other hand, the border trap (N_{bt}) is located within the insulator near the interface between the insulator and the channel having an energy level within the channel band gap. By replacing a carrier with a channel material, these traps can change the charge state, thereby significantly reducing device performance. These traps cause pinning of the Fermi level and lower carrier generation in the channel, thereby reducing the drive current and sub-threshold swing (SS).

A conductance method is known as a method of extracting interface traps (Dᵢₜ), and a distributed border trap model method is known as a method of extracting border traps (N_{bt}). Both methods use the measured gate capacitance (Cₘ) and conductivity (Gₘ) characteristics for trap extraction. The total gate capacitance (C_{g}) can be modeled as a series connection of insulator capacitance (Cᵢₙₛ) and inversion layer capacitance (Cᵢₙᵥ). The inversion layer capacitance (Cᵢₙᵥ) can be represented by two series capacitances known as quantum capacitance (C_{q}) and central capacitance (Cₑₙₜ). The quantum capacitance (C_{q}) arises from the implantation of the Fermi level (E_{F}) inside the conduction band (E_{C}), and the central capacitance is related to the average charge distance at the interface between the insulator and the channel.

In conventional Si-based MOS devices, the values of quantum capacitance (C_{q}) and center capacitance (Cₑₙₜ) are relatively large, so that the total gate capacitance (C_{g}) approaches oxide capacitance (Cₒₓ). However, in small-scale group III-V-based MOS devices, this capacitance tends to be smaller, is similar to the oxide capacitance (Cₒₓ), and makes the total gate capacitance (C_{g}) smaller.

By the way, in determining the oxide thickness for extracting interface traps (Dᵢₜ) and border traps (N_{bt}), a physical thickness (tₒₓ) or EOT is generally considered, but in group III-V-based MOS devices, there is a problem that various factors as mentioned above are not considered through the physical thickness (tₒₓ) or EOT.

### DISCLOSURE

### Technical Problem

It is an object of the present invention to provide a method for clearly extracting a surface trap level including interface traps and border traps in a device including a high-k dielectric and a group III-V compound semiconductor in consideration of quantum effects.

### Technical Solution

The present invention provides a method for extracting a surface trap level including an interface trap and a border trap by using a capacitance equivalent thickness (CET) capable of considering quantum effects in a device including a high-k dielectric and a group III-V compound semiconductor.

The device comprises an integrated circuit. The integrated circuit may be a memory cell, a logic circuit, a resistor, a capacitor, an inductor, a fuse, an MOSFET (metal-oxide-semiconductor field effect transistor), a CMOS (complementary metal-oxide-semiconductor transistor), a high-voltage transistor, or a high-frequency transistor.

The group III-V compound semiconductor and the high-k dielectric may be those satisfying General Equation 1 below in a gate voltage range of 0.5 to 1V.

E₂−E_{F}<0 [General Equation 1]

In Equation 1 above, E_{F} is the Fermi level (eV), and E₂ is the energy level (eV) of the second sub-band.

In addition, the group III-V compound semiconductor may be at least one selected from the group consisting of gallium arsenide (GaAs), indium gallium arsenide (InGaAs), and indium phosphate (InP).

The high-k dielectric may comprise at least one oxide selected from the group consisting of aluminum (Al), hafnium (Hf), zirconium (Zr), titanium (Ti), and lanthanum (La), and for example, the high-k dielectric may be at least one selected from Al₂O₃, HfO₂, La₂O₃, ZrO₂, and HfAlOx.

Referring to FIG. 2a, the total gate capacitance (C_{g}) of the group III-V compound MOS device can be represented by a series combination of insulator capacitance (Cᵢₙₛ) and inversion layer capacitance (Cᵢₙᵥ), considering that there is no doping level under the channel.

The inversion layer capacitance (Cᵢₙᵥ) consists of several parallel combinations of series-connected quantum capacitance (C_{q_i}) and center capacitance (C_{cent_i}), which indicate the contribution of each occupied electronic sub-band in the channel. The total inversion layer capacitance can be expressed as Equation 1 below.

$${C}_{inv \_ i} = \frac{\partial ( - {Q}_{s} )}{\partial {ψ}_{s}} = \frac{q \partial ( - {Q}_{s} )}{\partial ( {E}_{F} - {E}_{C} )} \qquad [ Equation 1 ]$$

In Equation 1 above, Qₛ represents the total electron charge in the channel, Ψₛ is the surface potential, E_{F} is the Fermi level, and E_{C} is the conduction band edge located at the insulator channel interface.

Qₛ, the sum of all sub-band charges, can be expressed as in Equation 2 below.

$${Q}_{s} = {\sum }_{i} {Q}_{i} = {\sum }_{i} \text{?} \frac{\frac{{m}_{∥}^{*} q}{{πℏ}^{2}}}{1 + {e}^{( \frac{E - {E}_{F}}{kT} )}} dE \qquad [ Equation 2 ]$$

$$\text{?} \text{indicates text missing or illegible when filed}$$

In Equation 2 above, Qi is the total electron charge of sub-band i located in the channel, Eᵢ is the energy level of sub-band i, and m_{∥}* represents the effective mass of the channel material.

The m_{∥}* can be calculated from Equation 3 below.

$${m}_{∥}^{*} = {m}_{0}^{*} ( 1 + α E ) = \frac{{ℏ}^{2} {k}^{2}}{2 E} \qquad [ Equation 3 ]$$

In Equation 3 above, mo* is the effective mass at k=0, E is the charge carrier energy, k is the charge carrier wave number, h is the reduced Planck constant, and α is a nonparabolicity parameter.

The quantum capacitance (C_{q_i}) of a specific sub-band i can be mathematically extracted from the derivative function of the electron charge of the specific sub-band with respect to the energy difference between E_{F} and Eᵢ, as shown in Equation 4 below.

$${C}_{q \_ i} = \text{?} \qquad [ Equation 4 ]$$

$$\text{?} \text{indicates text missing or illegible when filed}$$

In addition, the central capacitance (C_{cent_i}) can be derived from the derivative function of the electron charge of the specific sub-band i with respect to the energy difference between E_{F} and E_{C}, as shown in Equation 5 below.

$${C}_{cent \_ i} = \frac{q \partial ( - {Q}_{i} )}{\partial ( {E}_{F} - {E}_{C} )} = {C}_{q \_ i} \frac{\partial ( {E}_{F} - {E}_{i} )}{\partial ( {E}_{F} - {E}_{C} )} \qquad [ Equation 5 ]$$

From the above equation, the inversion layer capacitance (C_{inv_i}) can be expressed as Equation 6 below.

$${C}_{inv \_ i} = {\sum }_{i} {( \frac{1}{{C}_{q \_ i}} + \frac{1}{{C}_{cent \_ i}} )}^{- 1} \qquad [ Equation 6 ]$$

Knowing the locations of the respective sub-band energy level (Eᵢ) and Fermi level (E_{F}) with respect to the conduction band edge, the inversion layer capacitance can be calculated.

In the present invention, extraction of interface traps (Dᵢₜ) may use a conductivity method. The conductivity method analyzes losses caused by changes in the trap level charge state. As the response time τ is lowered, the traps with energy levels closer to the Fermi level (E_{F}) can change their occupancy.

FIG. 2b shows an equivalent circuit diagram of a MOS capacitor in a depleted state including interface traps. Cₒₓ is the oxide capacitance, Cₛ is the semiconductor capacitance, and Rₛ is series resistance. Here, Cᵢₜ and Gₚ are the equivalent parallel interface trap capacitance and conductivity formed by the interface trap, respectively. The interface trap capacitance means Cᵢₜ=qDᵢₜ, where q is the charge of the element and Dᵢₜ is the interface trap density. When electrons are captured by the interface traps, a direct contribution is made to the formation of interface trap capacitance Cᵢₜ. As shown in Equation 7 below, trap response can be measured by Shockley-Read-Hall statistics of capture and discharge rates.

$$τ = \frac{1}{2 π f} = \frac{1}{ω} = \frac{{e}^{( \frac{Δ E}{{K}_{B} T} )}}{σ {v}_{th} {D}_{dos}} \qquad [ Equation 7 ]$$

In Equation 7 above, ΔE is the energy difference between the trap level E_{T} and the main carrier band edge of E_{C} or EV, K_{B} is the Boltzmann constant, and T is the temperature. σ is the trap cross-section, vₜₕ is the average thermal velocity of the main carrier, and D_{dos} is the effective state density of the main carrier band.

FIG. 2b shows an equivalent circuit for analyzing impedance together with the measured capacitance Cₘ and the measured conductivity Gₘ, where such measured values must be corrected for the series resistance Rₛ, as shown in Equation 8 below.

$${R}_{s} = \frac{{G}_{ma}}{{G}_{ma}^{2} + {ω}^{2} {C}_{ma}^{2}} \qquad [ Equation 8 ]$$

In Equation 8 above, Cₘₐ and Gₘₐ are capacitance and conductivity measured in an accumulated state, respectively, and w is an angular frequency.

In addition, for the correction of capacitance and parallel equivalent conductivity, the following equations 9 and 10 may be used.

$${C}_{c} = \frac{( {G}_{m}^{2} + {ω}^{2} {C}_{m}^{2} ) {C}_{m}}{{[ {G}_{m} - ( {G}_{m}^{2} + {ω}^{2} {C}_{m}^{2} ) {R}_{s} ]}^{2} + {ω}^{2} {C}_{m}^{2}} \qquad [ Equation 9 ]$$

$${G}_{c} = \frac{( {G}_{m}^{2} + {ω}^{2} {C}_{m}^{2} ) [ {G}_{m} - ( {G}_{m}^{2} + {ω}^{2} {C}_{m}^{2} ) {R}_{s} ]}{{[ {G}_{m} - ( {G}_{m}^{2} + {ω}^{2} {C}_{m}^{2} ) {R}_{s} ]}^{2} + {ω}^{2} {C}_{m}^{2}} \qquad [ Equation 10 ]$$

The equivalent parallel conductivity can be measured using Equation 11 below.

$${G}_{p} = \frac{{ω}^{2} {C}_{ox} {G}_{c}}{{G}_{c}^{2} + {{ω}^{2} ( {C}_{ox} - {C}_{c} )}^{2}} \qquad [ Equation 11 ]$$

In Equation 11 above, Cₒₓ is the dielectric (oxide) capacitance. Therefore, Dᵢₜ can be calculated from the normalized parallel conductivity peak (Gp/w)ₘₐₓ, as shown in Equation 12 below.

$${D}_{u} \approx \frac{2.5}{Aq} {( \frac{{G}_{p}}{ω} )}_{max} \qquad [ Equation 12 ]$$

In Equation 12 above, A is the device area, which can determine the trap occupancy at the energy level using Equation 7, where f is the frequency determined from the conductivity peak (Gp/w)ₘₐₓ.

In the present invention, the border trap extraction has used a distributed circuit model. In general, the border trap in the insulator and the carrier moving in the semiconductor band can exchange charges. Typically, this charge exchange occurs through tunneling. The average time for an empty trap to capture an electron is denoted by τ, which is exponentially proportional to the distance x between the trap and the interface.

τ=τ₀e^{2kx} [Equation 13]

In Equation 13 above, t₀ is a capture/discharge time constant and k is an attenuation constant.

The attenuation constant is defined by Equation 13-1 below.

$$k = \frac{\sqrt{2 {m}^{*} \times {E}_{b}}}{ℏ} \qquad [ Equation 13 - 1 ]$$

In Equation 13-1 above, m* is the effective mass of the insulator, Eb is the height of the energy barrier between the insulator and the semiconductor conduction band, and h is the reduced Planck constant.

In addition, t₀ may be defined as in Equation 14 below.

τ₀=(nₛvₜₕσ)⁻¹ [Equation 14]

In Equation 14 above, nₛ is the electron density of the semiconductor surface, vₜₕ is the electron thermal velocity, and σ is the capture cross-section area of the border trap. When the device is in the accumulation state, the Fermi level is close to the conduction band. In this case, nₛ can be relatively equal to the density of states in the conduction band. Assuming that wt=1, the probing depth of the border trap at a certain applied frequency (f) can be measured as in Equation 15 below.

$${X}_{p} = \frac{1}{2 k} ln \frac{1}{2 π f {τ}_{0}} \qquad [ Equation 15 ]$$

FIG. 3 shows an equivalent circuit model for border trap extraction. For border trap extraction, the distributed border trap model analyzes the frequency distribution of the accumulated region at a specific gate bias voltage. In this model, the oxide capacitance is divided into elements with small capacitance. That is, it can be expressed as εₒₓ/Δx, where εₒₓ is the permittivity and Δx is a small fraction of the oxide thickness. The border trap-induced charge and the energy loss can be described by a series of admittances for a specific portion of thicknesses. The total admittance consists of a series connection of capacitance C_{bt} and conductivity G_{bt} connected in parallel to the insulator capacitance. The semiconductor capacitance Cₛ is connected in series, where the overall structure can be expressed by a first-order differential equation as in Equation 16 below.

$$\frac{\partial Y}{\partial x} = - \frac{{Y}^{2}}{j ω {ε}_{ox}} + \frac{{q}^{2} {N}_{bt} ln ( 1 + j ω τ )}{τ} \qquad [ Equation 16 ]$$

In Equation 16 above, the border conditions are x=0, and Y=jwCₛ (Y=total admittance), and j is the imaginary part of the complex number, w is the angular frequency, q is the electron charge, and N_{bt} is the border trap density of the oxide layer.

### Advantageous Effects

The method for extracting a surface trap level considering an oxide thickness of a quantum capacitor according to the present invention has an effect of enabling more accurate surface trap level measurement by extracting interface trap and border trap densities using a capacitance equivalent thickness (CET) in consideration of a quantum mechanical confinement effect in a group III-V compound device.

### DESCRIPTION OF DRAWINGS

FIG. 1a is a schematic diagram showing interface traps and border traps in a metal/insulator/semiconductor structure.

FIG. 1b is a schematic diagram showing a quantum confinement effect of a group III-V compound substrate.

FIG. 2a is a circuit diagram of equivalent gate capacitance of a group III-V field effect transistor.

FIG. 2b is an equivalent circuit diagram of a metal oxide semiconductor device in depletion mode.

FIG. 3 is an equivalent circuit diagram of a distributed bulk oxide trap model showing a metal oxide semiconductor element.

FIG. 4a is a graph comparing C-V characteristics between Al₂O₃/Si and Al₂O₃/In_{0.53}Ga_{0.47}As structures.

FIG. 4b is a graph showing sub-band energy levels for the Fermi level of the Al₂O₃/Si structure.

FIG. 4c is a graph showing the inversion layer capacitance of an Al2O3/Si structure.

FIG. 4d is a graph showing a sub-band energy level for a Fermi level of an Al₂O₃/In_{0.53}Ga_{0.47}As structure.

FIG. 4e is a graph showing inversion layer capacitance of an Al₂O₃/In_{0.53}Ga_{0.47}As structure.

FIG. 5a is a contour mapping graph of normalized parallel conductance (G_{P}/Δωq) as a function of applied gate biasing voltage and frequency.

FIG. 5b is a graph showing an interface trap distribution as a function of trap energy (E_{T}).

FIG. 6a is a graph showing interface trap densities extracted at different ALD deposition temperatures.

FIG. 6b is a graph comparing interface trap densities extracted using EOT and CET.

FIG. 7a is a graph showing a fitting curve for accumulated capacitance measured at a gate voltage of 1V in a distributed border trap model using EOT.

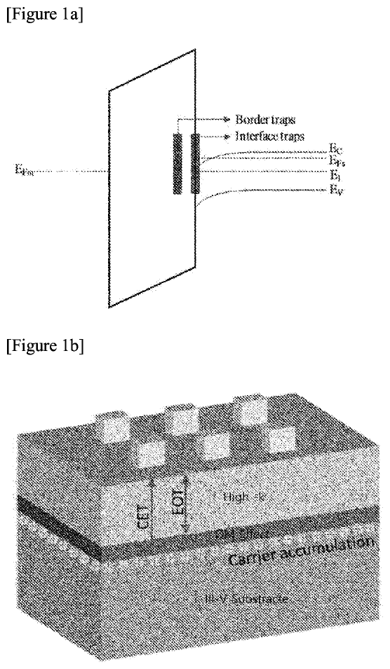

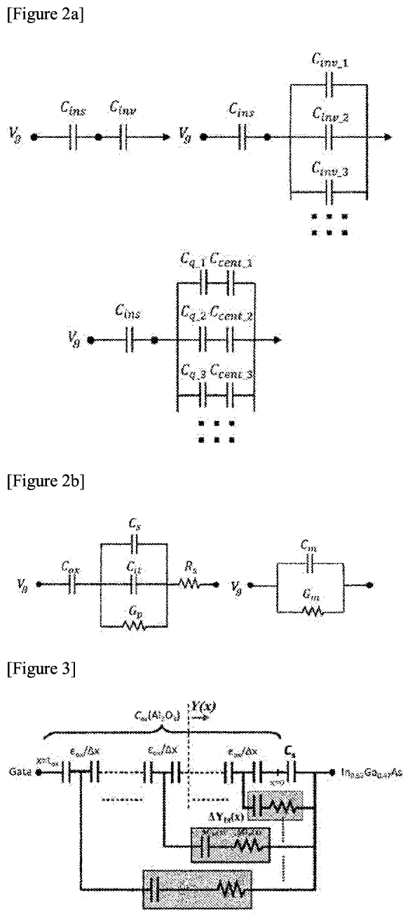

### BEST MODE

Since the present invention can make various changes and have various examples, specific examples will be illustrated in the drawings, and described particularly in the detailed description.

However, it is not intended to limit the present invention to specific embodiments, and should be understood to include all modifications, equivalents, or substitutes included in the spirit and technical scope of the present invention.

In the present invention, the term “comprise” or “have,” and the like is intended to designate that there is a feature, number, step, operation, component, part, or combination thereof described in the specification, but it should be understood that the possibility of the presence or addition of one or more other features, or numbers, steps, operations, components, parts, or combinations thereof is not precluded.

Therefore, the constitutions shown in the examples described in this specification are only one of the most preferred examples of the present invention and do not represent all of the technical ideas of the present invention, so that various equivalents and variations that can replace them at the time of filing the present application may exist.

In order to fabricate the n-type In_{0.53}Ga_{0.47}As heterostructure, metal organic chemical vapor deposition (MOCVD) was used. First, two strain relaxation buffer epitaxies of GaAs and InP were grown on a 300 mm n-type Si substrate. At this time, the Volmer-Weber growth mode was followed. The carrier concentrations of GaAs and InP each are 2×10¹⁷ cm⁻³ at thicknesses of 350 nm and 800 nm. Then, two successive layers of Si-doped n-In_{0.53}Ga_{0.47}As were formed. The first layer had an electron density of 5×10¹⁷ cm⁻³ and a thickness of 110 nm, and the second layer had an electron density of 1×10¹⁷ cm⁻³ and a thickness of 160 nm.

The present invention prepared three examples performed at different ALD oxide deposition temperatures. The substrate was cleaned with isopropyl alcohol and acetone for several minutes, and immersed in a solution of dilute hydrochloric acid and deionized water (1:10) at room temperature for 30 seconds so that no native oxide could be formed. Hereinafter, the substrate was washed with deionized water, and residual moisture on the surface of the substrate was removed using nitrogen (N₂). After cleaning, the substrate was disposed in an ALD chamber for oxide deposition. The ALD chamber was pre-cleaned with 10 cycles of trimethyl aluminum (TMA). Hereinafter, 30 cycles of Al₂O₃ were ALD-deposited at growth temperatures of 200° C. (Example 1), 250° C. (Example 2), and 300° C. (Example 3), respectively. TMA and water were used as a metal precursor and an oxidant, respectively, and nitrogen (N₂) flowing at 300 sccm was used as a carrier and purge gas. A 5 nm layer of TiN was deposited by ALD. A 200 nm layer of Au was deposited on both contacts of the front portion and rear portion by E-beam evaporation.

Prior to the front portion metal deposition, the physical thicknesses of the examples were extracted using ellipsometry (incidence angle=70°). The physical thicknesses tₒₓ of Examples 1 to 3 were measured to be 4.2006 nm, 3.867 nm and 3.5128 nm, respectively.

In order to extract the accurate effective permittivity constants (εₒₓ) of the samples, a metal insulator metal (MIM) capacitor was prepared. A 300 nm n-type Si substrate was pre-cleaned in the same manner as the above method. Hereinafter, the substrate was transferred to a thermal evaporator and Al was deposited as a bottom electrode using the thermal evaporator. The substrate was disposed in an ALD chamber for oxide deposition with 100 cycles of Al₂O₃ at 250° C. TMA and water were used as a metal precursor and an oxidant, respectively. In addition, nitrogen (N₂) at 300 sccm was used as a carrier and purge gas. Al was deposited as the front portion metal using thermal evaporation with a shadow mask.

All measurements of capacitance-voltage (C-V) and conductivity-voltage (G-V) were performed using a semiconductor device analyzer (Keysight B1500A) and a precision LCR meter (Agilent 4384A). The measurement frequency range was 10 KHz to 1 MHz, and the effective relative permittivity (c ox) was determined using Equation 17 below.

$${ε}_{ox} = \frac{{C}_{min} {t}_{min}}{{ε}_{0}} \qquad [ Equation 17 ]$$

In Equation 17 above, Cₘᵢₙ is the measured capacitance, and tₘᵢₙ is the thickness of the MIM capacitor.

For EOT and CET extraction, Equations 18 and 19 below were used.

$$EOT = \frac{3.9 \times {t}_{ox}}{{ε}_{ox}} \qquad [ Equation 18 ]$$

$$CET = \frac{3.9 \times {ε}_{0}}{{C}_{acc}} \qquad [ Equation 19 ]$$

In Equation 19 above, C_{acc} is the measured accumulated capacitance of the MOS capacitor.

In the present invention, using the Nextnano simulation tool, a consistent solution of the one-dimensional Poisson and Schrodinger equation was solved, and the total sheet charge density (Qₛ), sub-band energy (Eᵢ), conduction band (E_{C}), and Fermi level energy (E_{F}) were extracted with the same simulation tool. The capacitance of the MOS device was calculated by differentiating the total sheet charge density with respect to the applied gate bias voltage.

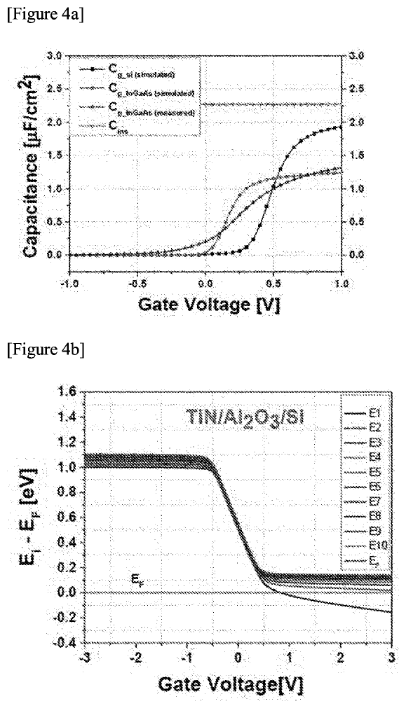

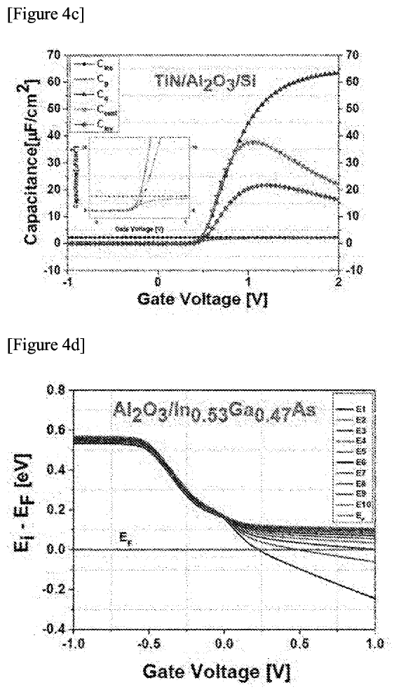

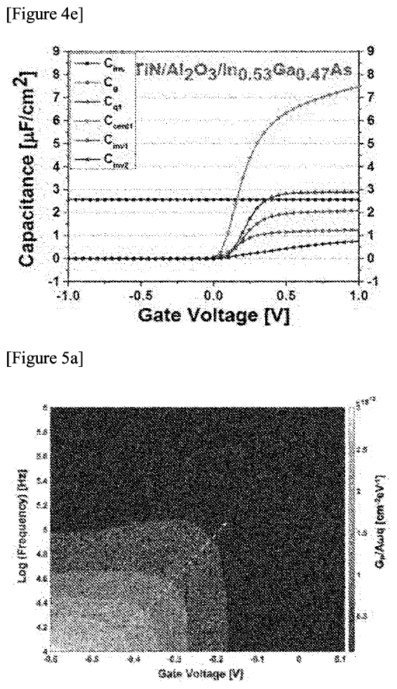

FIG. 4a shows simulated C-V curves and measured C-V curves of a reference example (Al₂O₃/Si) and an example (Al₂O₃/In_{0.53}Ga_{0.47}As). At this time, the ideal dielectric constant (k=9) and the measured thickness of Al₂O₃ were considered in order to determine the insulator capacitance (Cᵢₙₛ) Referring to FIG. 4a, the gate capacitance of the reference example (Si structure) is very close to the insulator capacitance, and thus it can be seen that there is no or very low inversion layer capacitance effect. On the other hand, the simulated and measured capacitance of the example (In_{0.53}Ga_{0.47}As) device shows a high effect of the inversion layer capacitance in the group III-V device scaled down as approximately 55 to 60% of Cᵢₙₛ.

FIGS. 4b and 4d show sub-band energy levels of a reference example (Al₂O₃/Si) and an example (Al₂O₃/In_{0.53}Ga_{0.47}As), respectively. In the Si structure, the Fermi level penetrates only in the first sub-band energy level (E₁). On the other hand, in the In_{0.53}Ga_{0.47}As structure, it penetrates in the first and second sub-band energy levels and is very close to the penetration in the third sub-band. In order to extract the inversion layer capacitance components, the conduction band effective masses of Si and In_{0.53}Ga_{0.47}As considering the non-parabolicity effect together were regarded to be 0.98 m₀ and 0.043 m₀, respectively. Here, m₀ is the rest mass of an electron.

FIGS. 4c and 4e show the inversion layer capacitance of a reference example (Al₂O₃/Si) and an example (Al₂O₃/In_{0.53}Ga_{0.47}As). Quantum capacitance (C_{q}) is related to the electron mobility, effective mass, and density of states (DOS) of the channel material. Referring to FIGS. 4c and 4e, it can be seen that C_{q} and C_{cent} of the Si substrate are very large compared to the insulator capacitance (Cᵢₙₛ). Due to this high value of inversion layer capacitance, the Si substrate has little or no effect on the gate capacitance. In contrast to this, in the In_{0.53}Ga_{0.47}As structure, it can be seen that Cᵢₙᵥ₁ is close to the insulator capacitance, and thus has a larger effect on the gate capacitance. Cᵢₙᵥ₂ is very small compared to Cᵢₙᵥ₁ due to the lower electron density in the second sub-band energy level.

An MIM capacitor was used to extract the dielectric constant of Al₂O₃. The dielectric constant was calculated to be 7.19 using Equation 17 above. Oxide capacitance (Cₒₓ) was calculated by dividing the total oxide permittivity by EOT or CET for each case. EOT and CET were calculated according to Equation 18 and Equation 19 above, respectively. In the CET calculation, C_{acc} is the capacitance value from a frequency of 100 KHz at a gate voltage of 1 V. In order to extract the densities (Dᵢₜ) of the interface traps of Reference Examples and Examples, the following procedure was used. The parallel conductivity (Gp) was measured by Equation 11 above using the calibrated and measured conductivity (G_{c}) and the calibrated and measured capacitance (C_{c}). Dᵢₜ was extracted using Equation 12 above using the parallel conductivity peak (Gp/w)ₘₐₓ. In Table 1 below, different parameter values used in the Dᵢₜ extraction process were represented.

TABLE 1

| | Example 1 | Example 2 | Example 3 |
|---|---|---|---|
| Parameter | (200° C.) | (250° C.) | (300° C.) |
| tₒₓ [nm] | 4.2006 | 3.867 | 3.5128 |
| EOT [nm] | 2.27 | 2.09 | 1.9 |
| CET [nm] | 2.89 | 2.7 | 2.36 |
| εₒₓ | 7.19 | 7.19 | 7.19 |
| m* [m₀] (Al₂O₃) | 0.23 | 0.23 | 0.23 |
| E_{b} [eV] | 3.6 | 3.6 | 3.6 |
| K [nm⁻¹] | 4.5 | 4.5 | 4.5 |
| C_{S} [μf/cm⁻²] | 1.1 | 1.14 | 1.2 |
| t₀ [s] (EOT use) | 1X10⁻¹² | 1X10⁻¹² | 1X10⁻¹³ |
| t₀ [s] (CET use) | 1X10⁻¹² | 1X10⁻¹² | 1X10⁻¹³ |
| Dᵢₜ [cm⁻²eV⁻¹] | 5.26X10¹¹ | 5.35X10¹¹ | 5.32X10¹¹ |
| (EOT use) | | | |
| Dᵢₜ [cm⁻²eV⁻¹] | 5.86X10¹¹ | 5.93X10¹¹ | 5.76X10¹¹ |
| (CET use) | | | |
| N_{bt} [cm⁻³eV⁻¹] | 2.32X10¹⁹ | 1.93X10¹⁹ | 2X10¹⁹ |
| (EOT use) | | | |
| N_{bt} [cm⁻³eV⁻¹] | 2.84X10¹⁹ | 2.56X10¹⁹ | 2.44X10¹⁹ |
| (CET use) | | | |

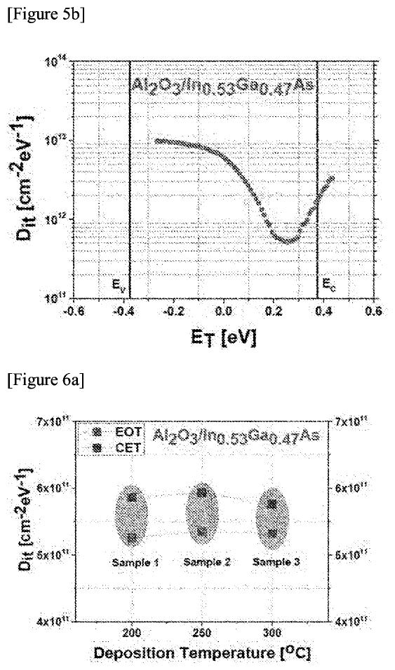

FIG. 5a shows a contour mapping of normalized parallel conductivity (Gₚ/Δwq) as a function of applied gate biasing voltage and measured frequency. The white oblique line represents the movement of the parallel conductivity peak (Gp/w)ₘₐₓ, which indicates the band bending efficiency and the degree of Fermi level immobilization. As the slope is steeper, it indicates effective band bending with less Fermi level immobilization. FIG. 5b graphically represents an interface trap state at the interface of a high-k/group III-V compound device with respect to the trap energy level. In order to assign the Dᵢₜ band energy position, E_{T} was determined by Equation 7 above. It was calculated from the corresponding frequency of (Gp/w)ₘₐₓ. The average thermal rate with and the effective density of states (Ddos) of n-type In_{0.53}Ga_{0.47}As at room temperature (300 K) were regarded as 5.6×10⁷ cms⁻¹ and 2.2×10¹⁷ cm⁻³, respectively, from “I. Vurgaftman, J. R. Meyer, and L. R. Ram-Mohan, “Band parameters for III-V compound semiconductors and from their alloys,” J. Appl. Phys., vol. 89, no. 11 I, pp. 5815-5875, 2001.” The capture cross-section value of In_{0.53}Ga_{0.47}As is 7×10⁻¹⁵ to 5×10⁻¹⁷ cm² by deep level transient spectroscopy. Since the error in σ does not significantly affect E_{T}, it was assumed to be 1×10⁻¹⁶ cm² in the range of the above values. At room temperature, E_{T} can vary by up to 60 meV/decade change of a, which is insignificant. The Dᵢₜ values appear higher near the edge of the valence band (E_{V}) compared to the edge of the conduction band (E_{C}). A similar drop in Dᵢₜ values for high-permittivity group III-V compound devices near the conduction band (E_{C}) edge using the conductivity method has also been reported in “G. Brammertz et al., “Capacitance-voltage characterization of GaAs—Al2O3 interfaces,” Appl. Phys. Lett., vol. 93, no. 18, pp. 1-4, 2008.”

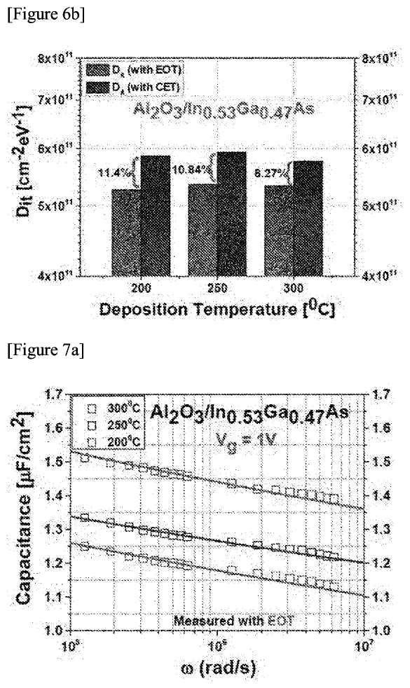

FIGS. 6a and 6b show the extracted values of the interface trap densities (Dᵢₜ). The Dᵢₜ values of the examples deposited at 200° C., 250° C. and 300° C. using EOT are 5.26×10¹¹ cm⁻² eV⁻¹, 5.35×10¹¹ cm⁻² eV⁻¹, and 5.32×10¹¹ cm⁻² eV⁻¹, respectively.

In the present invention, considering the quantum mechanical effect, CET was used instead of EOT in extracting Dᵢₜ, and other parameters were not changed. When using CET, the Dᵢₜ values of the examples deposited at 200° C., 250° C., and 300° C. are 5.86×10¹¹ cm⁻² eV⁻¹, 5.93×10¹¹ cm⁻² eV⁻¹, and 5.76×10⁼¹¹ cm⁻² eV⁻¹, respectively. The Dᵢₜ value extracted using CET has been confirmed to be up to 10% higher than the value extracted using EOT, which is due to quantum mechanical confinement.

In order to extract the border trap density (N_{bt}), the parameters in Table 1 were calculated. In order to calculate the attenuation coefficient, the effective mass of Al₂O₃ was regarded as 0.23 m₀ (where, m₀ is an electron mass in a stationary state). The Nextnano simulation tool was used to calculate the semiconductor capacitance C s at 1 V (border trap extraction voltage), as the one-dimensional Poisson-Schrodinger equation was interpreted considering quantum confinement. Equation 16 was used to generate the best fit curve for capacitance measured at 1 V, where N_{bt} and τ₀ were used as variables fitting the parameters.

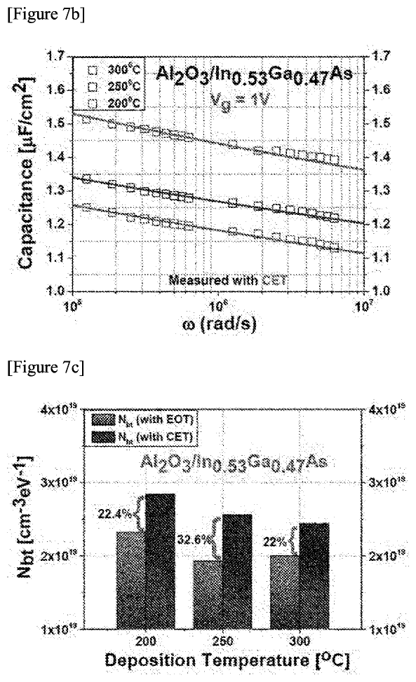

FIGS. 7a and 7b show border trap (N_{bt}) extraction fitting curves using EOT and CET, respectively. The squares represent the capacitance measured from different frequencies of 10 KHz to 1 MHz at 1 V and the straight line is the fitting curve.

FIG. 7c shows the differences between the extracted N_{bt} values of different Examples 1 to 3. Using EOT, the border trap (N_{bt}) values of the examples deposited at 200° C., 250° C. and 300° C. are 2.32×10¹⁹ cm⁻³ eV⁻¹, 1.93×10¹⁹ cm⁻³ eV⁻¹ and 2×10¹⁹ cm⁻³ eV⁻¹, respectively. At this time, the value of τ₀ is between 1×10⁻¹³ and 1×10⁻¹².

In order to consider the quantum mechanical effect, CET was used instead of EOT in extracting N_{bt} without changing other parameters except for N_{bt} and t₀ used as variables for fitting the parameters, as described above. The N_{bt} values extracted using CET were 2.84×10¹⁹ cm⁻³ eV⁻¹, 2.56×10¹⁹ cm⁻³ eV⁻¹ and 2.44×10¹⁹ cm⁻³ eV⁻¹ in the examples deposited at 200° C., 250° C. and 300° C., respectively, which was up to 25% or so higher than the values extracted from EOT like Dᵢₜ, and the value of τ₀ also existed between 1×10⁻¹³ and 1×10⁻¹².

The present invention confirmed an influence of a quantum mechanical confinement effect on an interface trap density (Dᵢₜ) and a border trap density (N_{bt}) in a group III-V metal oxide semiconductor device, and in order to show that the quantum confinement is more important in a small-scaled group III-V compound device, the Al₂O₃/Si and Al₂O₃/In_{0.53}Ga_{0.47}As structures were compared using the Nextnano simulation tool. As a result of the simulation, it was found that the inversion layer capacitance in the Si structure was very large compared to the insulator capacitance, and accordingly, there was no or very little effect on the total gate capacitance. On the other hand, in the Al₂O₃/In_{0.53}Ga_{0.47}As structure, the inversion layer capacitance was similar to the insulator capacitance and the total gate capacitance was lowered.

Al₂O₃/In_{0.53}Ga_{0.47}As MOS capacitors were fabricated on a 300 mm Si substrate at different oxide deposition temperatures, and all devices were subjected to a rapid thermal annealing (RTA) process. As a result of measuring the interface trap density (Dᵢₜ) and the border trap (N_{bt}) using both EOT and CET, the Dᵢₜ and N_{bt} values extracted using CET are about 10% and 25% or so higher, respectively, compared to the values extracted using EOT. The relatively low Dᵢₜ and N_{bt} values using EOT are caused by the additional thickness of the inversion layer, which is because the quantum effect in In_{0.53}Ga_{0.47}As has not been considered. Due to the additional thickness, it is speculated that the oxide-semiconductor interface is shifted more towards the channel and some additional interface traps capable of increasing the energy loss exist.

1. A method for extracting a surface trap level, including interface trap and border trap densities, in a device including a group III-V compound semiconductor and a high-k dielectric,
characterized by measuring interface trap and boundary trap densities using a capacitance equivalent thickness (CET).

2. The method for extracting a surface trap level according to claim 1, characterized in that
the group III-V compound semiconductor and the high-k dielectric are those satisfying General Equation 1 below in a gate voltage range of 0.5 to 1V.
E₂−E_{F}<0 [General Equation 1]
wherein, E_{F} is the Fermi level (eV), and E₂ is the energy level (eV) of the second sub-band.

3. The method for extracting a surface trap level according to claim 1, wherein
the group III-V compound semiconductor is at least one selected from the group consisting of gallium arsenide (GaAs), indium gallium arsenide (InGaAs), and indium phosphate (InP).

4. The method for extracting a surface trap level according to claim 1, wherein
the high-k dielectric comprises at least one oxide selected from the group consisting of aluminum (Al), hafnium (Hf), zirconium (Zr), titanium (Ti), and lanthanum (La).

5. The method for extracting a surface trap level according to claim 1, wherein
the capacitance equivalent thickness (CET) is measured by Equation 19 below:
$$CET = \frac{3.9 \times {ε}_{0}}{{C}_{acc}} \qquad [ Equation 19 ]$$
wherein,
ε₀ is the total high-k dielectric permittivity, and
C_{acc} is the capacitance value measured from a frequency of 100 KHz at a gate voltage of 1V.

6. The method for extracting a surface trap level according to claim 1, wherein
the interface trap density (Dᵢₜ) is measured using Equation 12 below:
$$Dit \approx \frac{2.5}{Aq} {( \frac{Gp}{ω} )}_{max} \qquad [ Equation 12 ]$$
wherein,
A is the device area, q is the charge, Gₚ is equivalent parallel conductance, and w is an angular frequency.

7. The method for extracting a surface trap level according to claim 6, wherein
the equivalent parallel conductivity is measured by Equation 11 below:
$${G}_{p} = \frac{{ω}^{2} {C}_{ox} {G}_{c}}{{G}_{c}^{2} + {{ω}^{2} ( {C}_{ox} - {C}_{c} )}^{2}} \qquad [ Equation 11 ]$$
wherein,
Cₒₓ is the conductivity of the high-k dielectric, G_{c} is corrected conductivity, and C_{c} is corrected capacitance.

8. The method for extracting a surface trap level according to claim 7, wherein
the corrected capacitance and the corrected conductivity are corrected by Equation 9 and Equation 10 below, respectively:
$${C}_{c} = \frac{( {G}_{m}^{2} + {ω}^{2} {C}_{m}^{2} ) {C}_{m}}{{[ {G}_{m} - ( {G}_{m}^{2} + {ω}^{2} {C}_{m}^{2} ) {R}_{s} ]}^{2} + {ω}^{2} {C}_{m}^{2}} \qquad [ Equation 9 ]$$
$${G}_{c} = \frac{( {G}_{m}^{2} + {ω}^{2} {C}_{m}^{2} ) [ {G}_{m} - ( {G}_{m}^{2} + {ω}^{2} {C}_{m}^{2} ) {R}_{s} ]}{{[ {G}_{m} - ( {G}_{m}^{2} + {ω}^{2} {C}_{m}^{2} ) {R}_{s} ]}^{2} + {ω}^{2} {C}_{m}^{2}} \qquad [ Equation 10 ]$$
wherein,
Gₘ is the measured conductivity, Cₘ is the measured capacitance, and Rₛ is series resistance.

9. The method for extracting a surface trap level according to claim 8, wherein
the series resistance is measured by Equation 8 below:
$${R}_{s} = \frac{{G}_{ma}}{{G}_{ma}^{2} + {ω}^{2} {C}_{ma}^{2}} \qquad [ Equation 8 ]$$
wherein,
Cₘₐ and Gₘₐ are capacitance and conductivity measured in an accumulated state, respectively.

10. The method for extracting a surface trap level according to claim 7, wherein
the capacitance of the high-k dielectric is calculated by dividing the total high-k permittivity by CET.

11. The method for extracting a surface trap level according to claim 1, wherein
the border trap density (N_{bt}) is measured using Equation 16 below:
$$\frac{\partial Y}{\partial x} = - \frac{{Y}^{2}}{j ω {ε}_{ox}} + \frac{{q}^{2} {N}_{bt} ln ( 1 + j ω τ )}{τ} \qquad [ Equation 16 ]$$
wherein,
x=0, Y is the total admittance, Y=jwCₛ,
j is the imaginary part of the complex number, w is the angular frequency, Cₛ is the capacitance of the semiconductor,
τ is an average time for an empty trap to capture an electron, and cox is the effective relative permittivity.

12. The method for extracting a surface trap level according to claim 11, wherein
the average time for an empty trap to capture an electron is defined by Equation 13 below:
τ=τ₀e^{2kx} [Equation 13]
wherein,
τ₀ is a capture/discharge time constant, k is an attenuation constant,
where the attenuation constant is defined by Equation 13-1 below,
$$k = \frac{\sqrt{2 {m}^{*} \times {E}_{b}}}{ℏ} \qquad [ Equation 13 - 1 ]$$
wherein,
m* is the effective mass of the insulator, E_{b} is the height of the energy barrier between the insulator and the semiconductor conduction band, and h is the reduced Planck constant.

13. The method for extracting a surface trap level according to claim 1, wherein
the interface trap density (Dᵢₜ) uses a conductivity method, and
the border trap density (N_{bt}) uses a distributed border trap model.
